(19) United States
(12) Patent Application Publication
(10) Pub. No.: US 2015/0323638 A1
(43) Pub. Date: Nov. 12, 2015

(54) NON-INVASIVE QUANTIFICATION OF CORONARY ARTERY FRACTIONAL FLOW RESERVE USING MRI

(71) Applicant: Cedars-Sinai Medical Center, Los Angeles, CA (US)

(72) Inventors: Debiao Li, South Pasadena, CA (US); Zhaoyang Fan, Hacienda Heights, CA (US)

(73) Assignee: CEDARS-SINAI MEDICAL CENTER, Los Angeles, CA (US)

(21) Appl. No.: 14/708,040

(22) Filed: May 8, 2015

Related U.S. Application Data
(60) Provisional application No. 61/992,122, filed on May 12, 2014.

(51) Int. Cl. G01R 33/563; G01F 1/716

(52) U.S. Cl. CPC G01R 33/56308; G01F 1/716

(57) ABSTRACT

A system for quantifying a fractional flow reserve (FFR) in a mammalian subject comprises implementing a multi-dimensional phase-contrast magnetic resonance sequence using an MRI scanner to scan a volume of interest (VOI) in the mammalian subject. The VOI comprises at least a portion of the mammalian subject's heart, one or more blood vessels, or both. A pressure gradient within a blood vessel segment of interest within the VOI is determined based on the implemented multi-dimensional phase-contrast magnetic resonance sequence. The determined pressure gradient is correlated to an FFR value.

### CROSS-REFERENCE TO RELATED APPLICATIONS

This application claims priority to and the benefits of U.S. Patent Application No. 61/992,122, filed on May 12, 2014, which is hereby incorporated by reference herein in its entirety.

### FIELD OF THE INVENTION

The present invention generally relates to imaging methods, and especially cardiovascular imaging methods.

### BACKGROUND

The following description includes information that may be useful in understanding the systems and methods described herein. It is not an admission that any of the information provided herein is prior art or relevant to the presently claimed invention.

Fractional flow reserve is generally considered a gold standard to evaluate the functional significance of an intermediate stenosis at the coronary arteries through measurement of pressure drop across stenosis. However, this is an invasive procedure and involves ionizing radiation exposure to patients.

### SUMMARY

According to one aspect of the present invention, a method for quantifying a fractional flow reserve (FFR) in a mammalian subject comprises implementing a multi-dimensional phase-contrast magnetic resonance sequence using an MRI scanner to scan a volume of interest (VOI) in the mammalian subject. The VOI comprises at least a portion of the mammalian subject's heart, one or more blood vessels, or both. A pressure gradient within a blood vessel segment of interest within the VOI is determined, via one or more processing units associated with the MRI scanner, based on the implemented multi-dimensional phase-contrast magnetic resonance sequence. The determined pressure gradient is correlated to an FFR value.

According to another aspect of the present invention, a magnetic resonance imaging system comprises a magnet operable to provide a magnetic field. A transmitter is operable to transmit to a region within the magnetic field. A receiver is operable to receive a magnetic resonance signal from the region. One or more processing units are operable to control the transmitter and the receiver. The one or more processing units are configured to direct the transmitter and receiver to execute a sequence comprising (a) acquiring magnetic resonance data from a volume of interest (VOI) comprising at least a portion of a mammalian subject's heart, one or more blood vessels, or both, the magnetic resonance data being acquired in response to implementation of a multi-dimension phase contrast magnetic resonance sequence; (b) determining a pressure gradient within a blood vessel segment of interest within the VOI based on the implemented multi-dimensional phase-contrast magnetic resonance sequence; (c) quantifying an fractional flow reserve (FFR) value based on the determined pressure gradient; (d) generating one or more images based on the magnetic resonance data acquired; and (e) displaying at least a portion of the generated image data on one of more graphical user interfaces coupled to the MRI scanner.

In a yet another aspect of the present invention, a non-transitory machine-readable medium has machine executable instructions stored in one or more memory devices coupled to one or more processors of a magnetic resonance imaging (MRI) machine. The instructions cause at least one of the one or more processors to implement acts comprising acquiring magnetic resonance data from a volume of interest (VOI) comprising at least a portion of a mammalian subject's heart, one or more blood vessels, or both. The magnetic resonance data is acquired in response to implementation of a multi-dimension phase contrast magnetic resonance sequence. A pressure gradient within a blood vessel segment of interest within the VOI is determined based on the implemented multi-dimensional phase-contrast magnetic resonance sequence. A fractional flow reserve (FFR) value for the mammalian subject is quantified based on the determined pressure gradient. One or more images are generated based on the magnetic resonance data acquired.

Additional aspects of the invention will be apparent to those of ordinary skill in the art in view of the detailed description of various embodiments, which is made with reference to the drawings, a brief description of which is provided below.

### BRIEF DESCRIPTION OF THE DRAWINGS

Exemplary embodiments are illustrated in the referenced figures. It is intended that the embodiments and figures disclosed herein are to be considered illustrative rather than restrictive.

FIG. 1 demonstrates, in accordance with one aspect of the present disclosure, exemplary images for a flow phantom at 0% and 44% stenosis.

FIG. 2 demonstrates, in accordance with one aspect of the present disclosure, an exemplary pressure difference associated with variable stenosis degrees in a flow phantom.

FIG. 3 demonstrates, in accordance with one aspect of the present disclosure, exemplary magnitude and phase images of the left anterior descending coronary artery for two cardiac phases in a healthy volunteer.

FIG. 4 depicts an exemplary magnetic resonance imaging system in accordance with one aspect of the present disclosure.

### DETAILED DESCRIPTION

All references cited herein are incorporated by reference in their entirety as though fully set forth. Unless defined otherwise, technical and scientific terms used herein have the same meaning as commonly understood by one of ordinary skill in the art to which this invention belongs. Westbrook et al., MRI in Practice 4^{th} ed., Wiley-Blackwell, (2011) and Guyton, A. C. and Hall, J. E., Textbook of Medical Physiology 12^{th} ed., Saunders Elsevier, Philadelphia (2011), provide one skilled in the art with a general guide to many of the terms used in the present application.

One skilled in the art will recognize many methods and materials similar or equivalent to those described herein, which could be used in the practice of the present invention. Indeed, the present invention is in no way limited to the methods and materials described. For purposes of exemplary aspects of the invention described by the present disclosure, certain terms are defined below.

“Conditions,” “disease conditions,” and “cardiovascular conditions,” as used herein, may include but are in no way limited to those conditions that are associated with stenosis.

“Mammal,” as used herein, refers to any member of the class Mammalia, including, without limitation, humans and nonhuman primates such as chimpanzees and other apes and monkey species; farm animals such as cattle, sheep, pigs, goats and horses; domesticated mammals, such as dogs and cats; laboratory animals including rodents such as mice, rats and guinea pigs, and the like. The term does not denote a particular age or sex. Thus, adult and newborn subjects, whether male or female, are intended to be included within the scope of this term.

“MR,” as used herein, is an acronym for magnetic resonance.

“MRI,” as used herein, is an acronym for magnetic resonance imaging.

“FFR,” as used herein, is an acronym for fractional flow reserve.

“PC,” as used herein, is an acronym for phase contrast.

“CT,” as used herein, is an acronym for computed tomography.

“LMA,” as used herein, is an acronym for left main artery.

“LAD,” as used herein, is an acronym for left anterior descending.

“LCX,” as used herein, is an acronym for left circumflex.

“VENC,” as used herein, is an acronym for velocity encoding.

FFR is a technique traditionally used in coronary catheterization to measure pressure differences across a coronary artery stenosis (narrowing, usually due to atherosclerosis) to determine the likelihood that the stenosis impedes oxygen delivery to the heart muscle (myocardial ischemia). FFR can be defined as the pressure behind (distal to) a stenosis relative to the pressure before the stenosis. The result is an absolute number. For example, an FFR of 0.80 means that a given stenosis causes a 20% drop in blood pressure. In other words, FFR expresses the maximal flow down a vessel in the presence of a stenosis compared to the maximal flow in the hypothetical absence of the stenosis.

Although CT has been used for measurement of FFR, it requires ionizing radiation and iodinated contrast media. MRI, on the other hand, does not impose the same risks. While phase-contrast MRI has been employed to measure the pressure gradient in the cardiac chamber, aorta, and renal arteries, MRI has not been previously used for FFR measurement. Non-invasive imaging systems and method that are safer and more efficient are desirable, such as the systems and methods that rely upon phase-contrast MRI technology for non-invasively quantifying FFR.

In some embodiments, a method of using MRI for quantifying FFR in a subject (e.g., a mammal) is described. In various embodiments, the method includes using an MRI scanner to scan a volume of interest (VOI) in the subject that includes all or a portion of the subject's heart and/or one or more blood vessels of interest. In some embodiments, the method includes using a multi-dimensional (e.g., 2D or 3D) PC-MR sequence, and calculating the pressure gradient within a vessel segment of interest. In certain embodiments, the multi-dimensional sequence is designed to measure the 4D flow velocity field through a cross-sectional 3D acquisition or a multi-slice 2D acquisition. In some embodiments, the method includes calculating the pressure gradient by using the Navier-Stokes equations, as described in Thompson, R. B. and McVeigh, E. R., “Fast Measurement of Intracardiac Pressure Differences with 2D Breath-Hold Phase-Contrast MRI,” Magnetic Resonance in Medicine, Wiley-Liss, Inc., Vol. 49, Issue 6, 1056-1066, June 2003, which is incorporated herein by reference in its entirety as though fully set forth. In Thompson et al., the velocity field was derived from a multi-slice 2D PC-MR acquisition within several breath-holds and through-plane velocity was not measured, which is applicable for the pressure quantification in the cardiac ventricle. For the small-caliber coronary artery, however, a PC-MR acquisition with respiratory navigator-gating and three-direction velocity measurement is needed to improve the quantification accuracy. In some embodiments, the cardiac-phase-resolved (2-3 cardiac phases) 3D or multi-slice 2D PC-MR data acquired during the coronary quiescent period undergoes image reconstruction using generic Fourier transform methods. A 4D flow velocity field is derived from the reconstructed phase images. As with Thompson et al, calculation of velocity derivatives and pressure gradient field are conducted on the flow velocity field. Transtenotic pressure difference is obtained by integration of the pressure gradient filed along a path manually drawn through the stenosis.

By way of non-limiting examples, it is demonstrated that the VOI in the subject, such as a mammalian subject, can include one or more vessels, including: LMA, proximal LAD artery, and LCX artery. In certain embodiments, a VENC of 90z40x40y cm/s is used to assess the left main artery. In various embodiments, a VENC of 60z30x30y cm/s is used to assess the proximal LAD. In some embodiments, a VENC of 60z30x30y cm/s is used to assess the LCX artery. A VENC that is anywhere within certain ranges, such as from 60-90(z)/20-40(x)/20-40(y) cm/s, is also contemplated.

In certain embodiments, the imaging parameters include an in-plane spatial resolution within a range of 0.5 mm to 0.7 mm. In some embodiments, slice thickness is within a range of 2 mm to 3 mm. In certain embodiments, the flip angle is within a range of 10° to 20°. In various embodiments, the cardiac phase is within a range of 2 to 3 at 30 to 70 ms/phase. In some embodiments, the scan time is within a range of 10 to 20 min.

In an embodiment, imaging parameters are as follows: in-plane spatial resolution=0.72×0.72 mm², slice thickness=2 mm, flip angle=15°, cardiac phase=2-3 (72 ms/phase) coinciding with the quiescent period, and scan time=11-18 minutes. In certain embodiments, the acquisition window for the MRI scan is limited to the mid-diastole and end-expiration phase by using ECG-triggering and navigator-gating.

In various embodiments, an MRI system, applying the processes described in the present disclosure, is used. In some embodiments, the system includes: a magnet operable to provide a magnetic field; a transmitter operable to transmit to a region within the magnetic field; a receiver operable to receive a magnetic resonance signal from the region; and a processor operable to control the transmitter and the receiver. In certain embodiments, the processor is configured to direct the transmitter and receiver to execute a sequence, including: (a) acquiring magnetic resonance data from a volume of interest (VOI) including all or a portion of the subject's heart and/or one or more blood vessels; and (b) generating one or more images using any of the schemes described herein, wherein a processor of the MRI machine is configured to (1) generate one or more images based on the magnetic resonance data acquired, and (2) quantify FFR based upon the magnetic resonance data acquired.

In some embodiments, the invention teaches a non-transitory machine-readable medium having machine executable instructions for causing one or more processors of a magnetic resonance imaging (MRI) machine to execute a method. In some embodiments, the method includes (1) acquiring magnetic resonance data from a volume of interest (VOI) including all or a portion of a subject's heart and/or one or more blood vessels of interest, according to the methods described herein; (2) generating one or more images based on the magnetic resonance data, using any of the image generating methods described herein; and (3) quantifying FFR based upon the magnetic resonance data.

In various embodiments, the scanning described herein is performed on a 3T MRI scanner. In some embodiments, the scanning described herein is performed on a 1.5T MRI scanner.

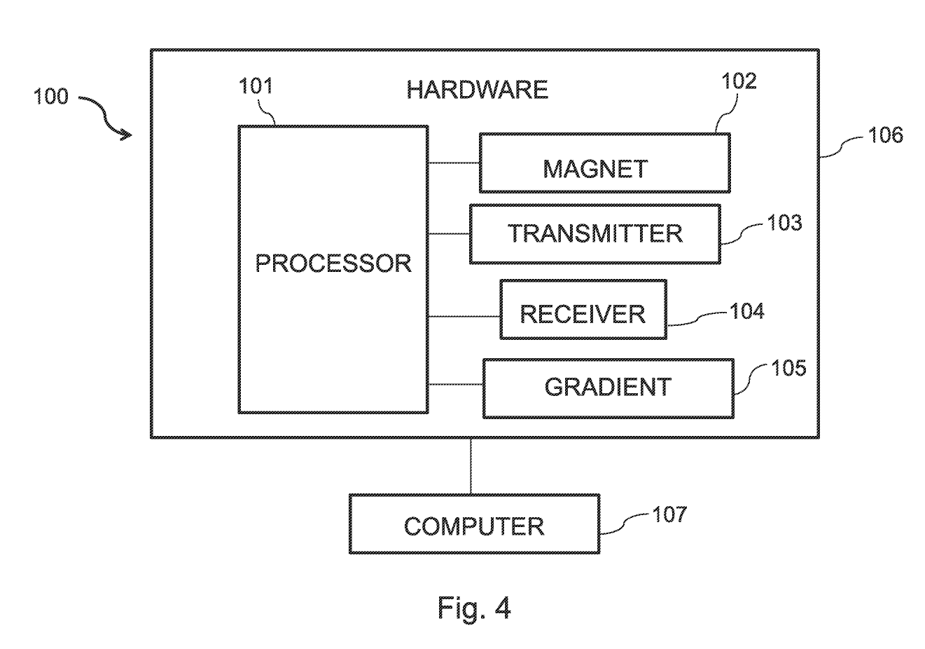

One of skill in the art would also readily appreciate that several different types of imaging systems could be used to perform the methods described herein. Merely by way of example, the imaging system described in the examples could be used. FIG. 4 depicts an exemplary view of a system 100 that can be used to accomplish the described methods. System 100 includes hardware 106 and computer 107. Hardware 106 includes a magnet 102, a transmitter 103, a receiver 104, and a gradient 105, all of which are in communication with a processor 101. The magnet 102 can include a permanent magnet, a superconducting magnet, or other type of magnet. The transmitter 103 along with the receiver 104, are part of the RF system. The transmitter 103 can represent a radio frequency transmitter, a power amplifier, and an antenna (or coil). The receiver 104, as denoted in the figure, can represent a receiver antenna (or coil) and an amplifier. In the example shown, the transmitter 103 and the receiver 104 are separately represented, however, in one example, the transmitter 103 and the receiver 104 can share a common coil. The hardware 106 includes the gradient 105. The gradient 105 can represent one or more coils used to apply a gradient for localization.

The processor 101, in communication with various elements of the hardware 106, includes one or more processors or one or more processing units configured to implement a set of instructions corresponding to any of the methods disclosed herein. The processor 101 can be configured to implement or execute a set of instructions (stored in memory of the hardware 106) to provide RF excitation and gradients and receive magnetic resonance data from a volume of interest. One of skill in the art would readily appreciate that certain components of the imaging systems described herein, including the processor 101, are used to execute instructions embedded on a computer readable medium to implement the inventive data acquisition, image reconstruction, and FFR quantification methods described herein.

In some embodiments, a computer 107 is operably coupled to the hardware 106. The computer 107 can include one or more of a desktop computer, a workstation, a server, or a laptop computer. In one example, the computer 107 is user-operable and includes a display, a printer, a network interface or other hardware to enable an operator to control operation of the system 100.

In various embodiments, a non-transitory machine-readable medium includes machine executable instructions for causing one or more processors of an MRI machine (such as those described herein) to execute a method, including (1) applying the MR sequence of any of the preceding or ensuing embodiments to a volume of interest (VOI) in a subject, wherein the VOI includes a region of the subject's heart and/or one or more blood vessels; (2) acquiring MR data from the volume of interest (VOI) in the subject; (3) generating one or more images based on the magnetic resonance data using an image generating (reconstruction) technique described herein; and (4) quantifying FFR according to one or more methods described herein.

In some embodiments, any of the methods or systems described herein can be used to diagnose a subject, such as a mammalian subject, with the presence or absence of a cardiovascular disease or condition, including stenosis, based upon the images acquired. In various embodiments, the stenosis is mild. In some embodiments, the stenosis is moderate. In some embodiments, the stenosis is severe.

One skilled in the art will recognize many methods and materials similar or equivalent to those described herein, which could be used in the practice of the present invention. Indeed, the present invention is in no way limited to the methods and materials described.

### EXAMPLES

### Example 1

An exemplary method included implementing a 3D PC-MR sequence with an acquisition window of 2-3 cardiac phases on a 3T system (MAGNETOM Verio, Siemens). To minimize motion-induced errors, the acquisition window was limited to the mid-diastole and end-expiration phase by using ECG-triggering and navigator-gating. The sequence was designed to measure the 4D flow velocity field through a cross-sectional 3D acquisition, used in conjunction with the Navier-Stokes equations employed to calculate the pressure gradient within the vessel segment of interest (See Thompson, R. B. and McVeigh, E. R., “Fast Measurement of Intracardiac Pressure Differences with 2D Breath-Hold Phase-Contrast MRI,” Magnetic Resonance in Medicine, Wiley-Liss, Inc., Vol. 49, Issue 6, 1056-1066, June 2003, which is incorporated by reference herein as though fully set forth.). A flow phantom study (gadolinium-doped water flow at a constant volume velocity of 250 mL/min in a silicone tubing of 4.8-mm ID) was first performed to determine the feasibility of the technique to detect changes in pressure gradients at different stenosis (0%, 20%, 40%, 60%). The sequence was then tested in three healthy human male volunteers on the left main, proximal LAD, or LCX coronary using a VENC of 90z40x40y cm/s, 60z30x30y cm/s, and 60z30x30y cm/s, respectively. Relevant imaging parameters for human studies were: in-plane spatial resolution=0.72×0.72 mm², slice thickness=2 mm, flip angle=15°, cardiac phase=2-3 (72 ms/phase) coinciding with the quiescent period, scan time=11-18 mins.

### Example 2

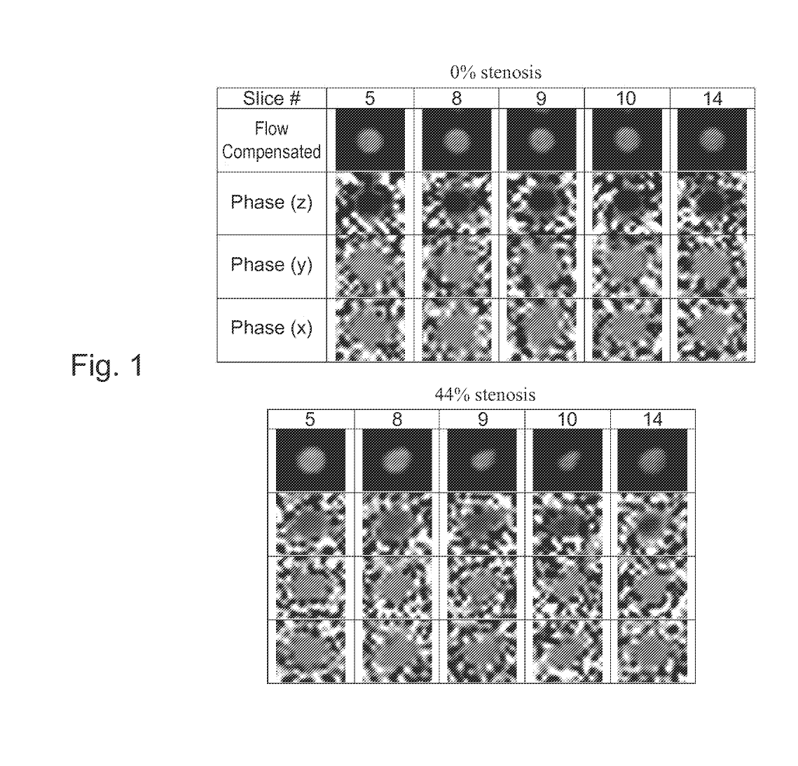

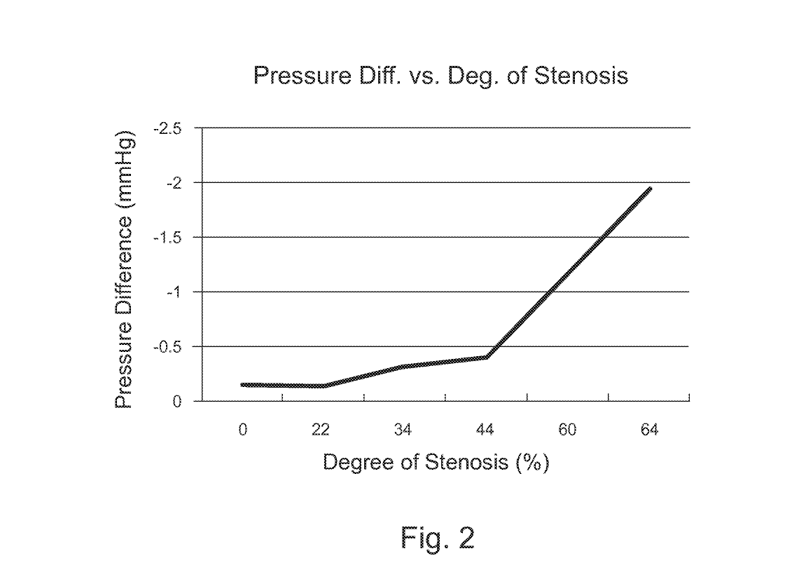

In certain exemplary aspects, scans were complete as part of phantom studies. Based on 2D velocity scout scans, appropriate combinations of VENCs in z (45, 60, . . . , 200 cm/s) and x, y (20, 30, . . . , 80 cm/s) directions were used for six stenotic cases: 0, 22%, 34%, 44%, 60%, 64%. A total of sixteen contiguous slices were acquired spanning the stenosis area. FIG. 1 shows the example magnitude/phase images for stenosis of 0 and 44%, respectively. The pressure difference (ΔP) between the most stenotic slice and the reference (2^{nd}) slice increased with the stenosis degree, as illustrated in FIG. 2.

### Volunteer Studies

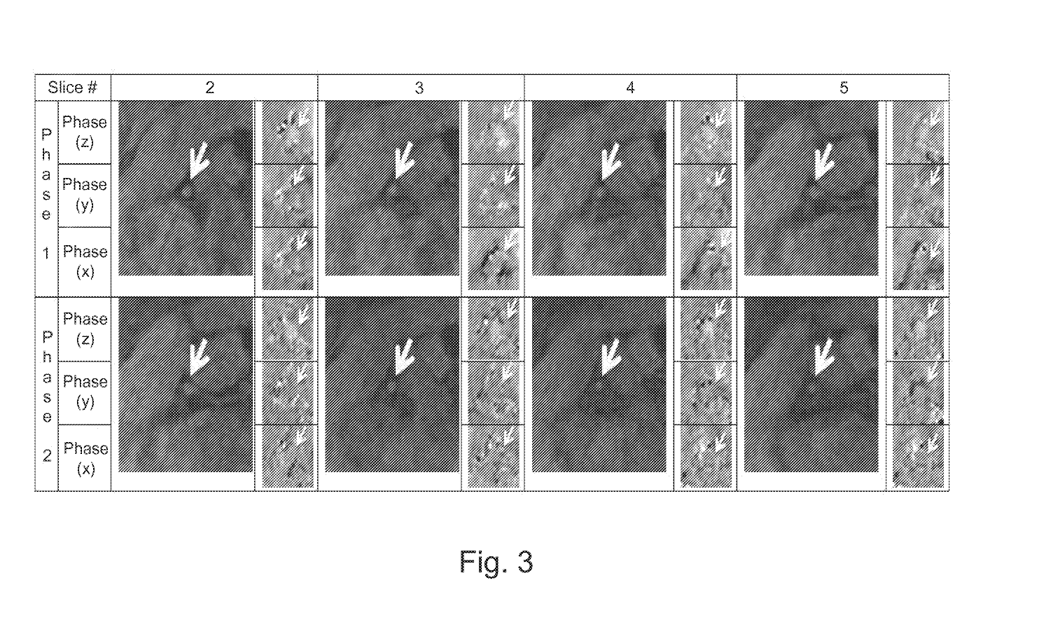

Six contiguous slices were acquired per volunteer. FIG. 3 illustrates the representative flow compensated/phase images of one volunteer from two successive cardiac phases during the mid-diastole, where the arrows are pointing at the cross-sections of the coronary artery. Cardiac phases in the z- and x,y-direction differed by 6-15 cm/s and 0.5-5 cm/s, respectively. AP values between slices two and five were 0.1646, 0.1407 and 0.2259 mmHg in the three human male volunteers, respectively.

### Example 3

In some embodiments, quantification of the pressure gradient at coronary arteries is described. Healthy human volunteer data has shown a near zero pressure gradient across the coronary arteries. The approached described herein could allow for noninvasive FFR measurement.

The various methods and techniques described above provide a number of ways to carry out the quantification of FFR in a mammalian subject. It would be understood that not necessarily all objectives or advantages described can be achieved in accordance with any particular embodiment described herein. Thus, for example, those skilled in the art will recognize that the methods can be performed in a manner that achieves or optimizes one advantage or group of advantages as taught herein without necessarily achieving other objectives or advantages as taught or suggested herein. A variety of alternatives are mentioned herein. It is to be understood that some preferred embodiments specifically include one, another, or several features, while others specifically exclude one, another, or several features, while still others mitigate a particular feature by inclusion of one, another, or several advantageous features.

Furthermore, the skilled artisan will recognize the applicability of various features from different embodiments. Similarly, the various elements, features and steps discussed above, as well as other known equivalents for each such element, feature or step, can be employed in various combinations by one of ordinary skill in this art to perform methods in accordance with the principles described herein. Among the various elements, features, and steps some will be specifically included and others specifically excluded in diverse embodiments.

Although the application has been disclosed in the context of certain embodiments and examples, it will be understood by those skilled in the art that the embodiments of the application extend beyond the specifically disclosed embodiments to other alternative embodiments and/or uses and modifications and equivalents thereof.

In some embodiments, the terms “a” and “an” and “the” and similar references used in the context of describing a particular embodiment of the application (especially in the context of certain of the following claims) can be construed to cover both the singular and the plural. The recitation of ranges of values herein is merely intended to serve as a shorthand method of referring individually to each separate value falling within the range. Unless otherwise indicated herein, each individual value is incorporated into the specification as if it were individually recited herein. All methods described herein can be performed in any suitable order unless otherwise indicated herein or otherwise clearly contradicted by context. The use of any and all examples, or exemplary language (for example, “such as”) provided with respect to certain embodiments herein is intended merely to better illuminate the application and does not pose a limitation on the scope of the application otherwise claimed. No language in the specification should be construed as indicating any non-claimed element essential to the practice of the application.

All patents, patent applications, publications of patent applications, and other material, such as articles, books, specifications, publications, documents, things, and/or the like, referenced herein are hereby incorporated herein by this reference in their entirety for all purposes, excepting any prosecution file history associated with same, any of same that is inconsistent with or in conflict with the present document, or any of same that may have a limiting affect as to the broadest scope of the claims now or later associated with the present document. By way of example, should there be any inconsistency or conflict between the description, definition, and/or the use of a term associated with any of the incorporated material and that associated with the present document, the description, definition, and/or the use of the term in the present document shall prevail.

In closing, it is to be understood that the embodiments of the application disclosed herein are illustrative of the principles of the embodiments of the application. Other modifications that can be employed can be within the scope of the application. Thus, by way of example, but not of limitation, alternative configurations of the embodiments of the application can be utilized in accordance with the teachings herein. Accordingly, embodiments of the present application are not limited to that precisely as shown and described.

What is claimed is:

1. A method for quantifying a fractional flow reserve (FFR) in a mammalian subject, comprising:
implementing a multi-dimensional phase-contrast magnetic resonance sequence using an MRI scanner to scan a volume of interest (VOI) in the mammalian subject, wherein the VOI comprises at least a portion of the mammalian subject's heart, one or more blood vessels, or both; and
determining, via one or more processing units associated with the MRI scanner, a pressure gradient within a blood vessel segment of interest within the VOI based on the implemented multi-dimensional phase-contrast magnetic resonance sequence, the determined pressure gradient being correlated to an FFR value.

2. The method of claim 1, wherein the phase-contrast magnetic resonance sequence is a multi-slice two-dimensional phase contrast sequence.

3. The method of claim 1, wherein the phase-contrast magnetic resonance sequence is a three-dimensional phase contrast sequence.

4. The method of claim 1, wherein the pressure gradient is determined using Navier-Stokes equations.

5. The method of claim 1, wherein the VOI comprises a blood vessel selected from the group consisting of a left main (LM) artery, a proximal left anterior descending (LAD) artery, and a left circumflex (LCX) artery.

6. The method of claim 5, wherein a velocity encoding (VENC) within a range of 60-90z/20-40x/20-40y cm/s is used to assess the blood vessel.

7. The method of claim 5, wherein a VENC of 90z40x40y cm/s is used to assess the LM artery.

8. The method of claim 5, wherein a VENC of 60z30x30y cm/s is used to assess the proximal LAI) artery.

9. The method of claim 5, wherein a VENC of 90z40x40y cm/s is used to assess the LCX artery.

10. The method of claim 1, wherein in-plane spatial resolution for the MRI scan is in the range of 0.5 mm to 0.7 mm.

11. The method of claim 1, wherein slice thickness for the MRI scan is in the range of 10° to 20°.

12. The method of claim 1, wherein the flip angle for the MRI scan is in the range of 10° to 20°.

13. The method of claim 1, therein the cardiac phase for MRI scan is in the range of 2 to 3 at 30 to 70 ms/phase.

14. The method of claim 1, wherein the scan time is in the range of 10 to 20 min.

15. The method of claim 1, wherein MRI scan includes an acquisition window that is limited to a mid-diastole and end-expiration phase by using ECG-triggering and navigator-gating.

16. A magnetic resonance imaging system, comprising:
a magnet operable to provide a magnetic field;
a transmitter operable to transmit to a region within the magnetic field;
a receiver operable to receive a magnetic resonance signal from the region; and
one or more processing units operable to control the transmitter and the receiver;
wherein the one or more processing units are configured to direct the transmitter and receiver to execute a sequence, comprising
(a) acquiring magnetic resonance data from a volume of interest (VOI) comprising at least a portion of a mammalian subject's heart, one or more blood vessels, or both, the magnetic resonance data being acquired in response to implementation of a multi-dimension phase contrast magnetic resonance sequence;
(b) determining a pressure gradient within a blood vessel segment of interest within the VOI based on the implemented multi-dimensional phase-contrast magnetic resonance sequence;
(c) quantifying an fractional flow reserve (FFR) value based on the determined pressure gradient;
(d) generate one or more images based on the magnetic resonance data acquired; and
(e) displaying at least a portion of the generated image data on one of more graphical user interfaces coupled to the MRI scanner.

17. The magnetic imaging system of claim 16, wherein the phase-contrast magnetic resonance sequence is a multi-slice two-dimensional or a three dimensional phase contrast sequence.

18. The magnetic imaging system of claim 16, wherein the VOI comprises a blood vessel selected from the group consisting of a left main (LM) artery, a proximal left anterior descending (LAD) artery, and a left circumflex (LCX) artery, and wherein a velocity encoding (VENC) within a range of 60-90z/20-40x/20-40y cm/s is used to assess the blood vessel.

19. A non-transitory machine-readable medium having machine executable instructions stored in one or more memory devices coupled to one or more processors of a magnetic resonance imaging (MRI) machine, the instructions causing at least one of the one or more processors to implement acts comprising:
acquiring magnetic resonance data from a volume of interest (VOI) comprising at least a portion of a mammalian subject's heart, one or more blood vessels, or both, the magnetic resonance data being acquired in response to implementation of a multi-dimension phase contrast magnetic resonance sequence;
determining a pressure gradient within a blood vessel segment of interest within the VOI based on the implemented multi-dimensional phase-contrast magnetic resonance sequence;
quantifying a fractional flow reserve (FFR) value for the mammalian subject based on the determined pressure gradient; and
generating one or more images based on the magnetic resonance data acquired.

20. The non-transitory machine readable medium of claim 19, the instructions causing the one or more processors to implement acts further comprising displaying at least a portion of the generated image data on one of more graphical user interfaces coupled to the MRI machine.
